(19) United States
(12) Patent Application Publication
(10) Pub. No.: US 2025/0343081 A1
(43) Pub. Date: Nov. 6, 2025

(54) MANUFACTURING METHOD OF TEST ELEMENT GROUP FOR METAL ROUTING LAYER

(71) Applicant: NANYA TECHNOLOGY CORPORATION, New Taipei City (TW)

(72) Inventors: Chun Hua SHIH, New Taipei City (TW); Jui-Hsiu JAO, New Taipei City (TW)

(21) Appl. No.: 19/267,642

(22) Filed: Jul. 14, 2025

Related U.S. Application Data
(62) Division of application No. 18/061,476, filed on Dec. 4, 2022.

(51) Int. Cl. H01L 21/66; G01R 31/28

(52) U.S. Cl. CPC H01L 22/32; G01R 31/2884

(57) ABSTRACT

A manufacturing method of a test element group for a metal routing layer comprises forming a metal layer on a substrate, and patterning the metal layer to form a plurality of first gaps to define a line region from a bulk region, in which the line region comprises a connection portion and a plurality of comb teeth portions connected to and perpendicular to the connection portion. Each of the comb teeth portions has a plurality of extending segments that are separated from each other. The bulk region surrounds the extending segments of the comb teeth portions. The first gaps respectively extend along outlines of the comb teeth portions.

### PRIORITY CLAIM AND CROSS-REFERENCE

The present application is a Divisional application of U.S. patent application Ser. No. 18/061,476, filed Dec. 4, 2022, which is herein incorporated by reference in its entirety.

### BACKGROUND

### Field of Invention

The present disclosure relates to a manufacturing method of a test element group for a metal routing layer.

### Description of Related Art

Integrated circuit chips are widely used in electronic products nowadays. As is well known to those having skill in the art, the internal circuits of integrated circuit chips generally include interconnected semiconductor devices such as diodes, transistors, capacitors and other devices. With the increasing advancement of technology, the width and spacing within metal routing layer providing equipotential contact in the integrated circuits is becoming smaller to achieve wafers with denser semiconductor devices. As the metal lines and spacing are thin enough, micro-defects will directly affect product reliability and induce the metal-metal short issue; therefore, the design and process ability become more important. Hence, a wafer acceptance test including the spacing test is applied. For the spacing test, spacing test element groups (TEG) are formed on the dies or the scribe lines between adjacent dies to inspect whether there is any micro metal residue killing product reliability, which is the potential risk called infant mortality. The TEG is configured to be contacted with a test apparatus including a test probe by TEG pads. After the electric connection, the test apparatus is allowed to measure electrical characteristics of the TEG, which can provide corresponding electrical characteristics of the metal routing layer of the dies. However, with the improvement of manufacturing techniques, traditional TEGs having the same comb shape cannot define all kinds of metal routing layers and detect the metal-metal short issue within.

### SUMMARY

One aspect of the present disclosure provides a manufacturing method of a test element group for a metal routing layer.

According to some embodiments of the present disclosure, a manufacturing method of a test element group for a metal routing layer comprises forming a metal layer on a substrate, and patterning the metal layer to form a plurality of first gaps to define a line region from a bulk region, in which the line region comprises a connection portion and a plurality of comb teeth portions connected to and perpendicular to the connection portion. Each of the comb teeth portions has a plurality of extending segments that are separated from each other. The bulk region surrounds the extending segments of the comb teeth portions. The first gaps respectively extend along outlines of the comb teeth portions.

In some embodiments, the manufacturing method of a test element group further includes simultaneously patterning the metal layer to form a second gap to define the connection portion of the line region and an edge of the bulk region when patterning the metal layer to form the first gaps.

In some embodiments, patterning the metal layer to form the first gaps and patterning the metal layer to form second gap are performed by photolithography.

In some embodiments, the second gap is between the bulk region and the connection portion of the line region.

In some embodiments, the comb teeth portions of the line region extend along a lengthwise direction of the bulk region.

In some embodiments, the comb teeth portions of the line region extend along a widthwise direction of the bulk region.

In some embodiments, any two adjacent extending segments of each of the comb teeth portions have a same distance.

In some embodiments, the extending segments of each of the comb teeth portions are line-shaped and parallel to a lengthwise direction of the connection portion.

In some embodiments, each of the comb teeth portions presents a cross-shaped profile when viewed from above.

In some embodiments, the extending segments of each of the comb teeth portions are fork-shaped.

In the aforementioned embodiments of the present disclosure, because the test element group for the metal routing layer includes the line region and the bulk region, and the comb teeth portions of the line region are separated from the bulk region by the first gaps that respectively extend along the outlines of the comb teeth portions, the test element group can be designed to monitor metal-metal short issue in a new metal routing design which cannot be defined by a traditional comb-shaped test element group. With the increasing advancement of manufacturing process, the interconnected semiconductor devices such as diodes, transistors, capacitors and other devices become smaller, and the test element group including the line region and the bulk region can monitor the new metal routing layers and inspect whether there is any micro metal residue inducing metal-metal short issue. Moreover, the area of the bulk region is larger than the area of the traditional comb-shaped test element group, and thus diverse patterns can be defined. The specific shape of the extending segments can be applied to the metal routing layer in integrated circuits simultaneously.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a test element group for a metal routing layer according to one embodiment of the present disclosure.

FIG. 2 is a top view of a test element group for a metal routing layer according to another embodiment of the present disclosure.

FIG. 3 is a top view of a test element group for a metal routing layer according to yet another embodiment of the present disclosure.

FIG. 4 is a top view of a test element group for a metal routing layer according to still another embodiment of the present disclosure.

FIG. 5 is a top view of a test element group for a metal routing layer according to one embodiment of the present disclosure.

FIG. 6 is a top view of a test element group for a metal routing layer according to another embodiment of the present disclosure.

FIG. 7 is a top view of a test element group for a metal routing layer according to yet another embodiment of the present disclosure.

FIG. 8 is a top view of a test element group for a metal routing layer according to still another embodiment of the present disclosure.

FIG. 9 is a top view of a test element group for a metal routing layer according to one embodiment of the present disclosure.

FIG. 10 is a top view of a test element group for a metal routing layer according to another embodiment of the present disclosure.

FIG. 11 is a flowchart of a manufacturing method of a test element group for a metal routing layer according to some embodiment of the present disclosure.

### DETAILED DESCRIPTION

The following disclosure provides many different embodiments, or examples, for implementing different features of the provided subject matter.

Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

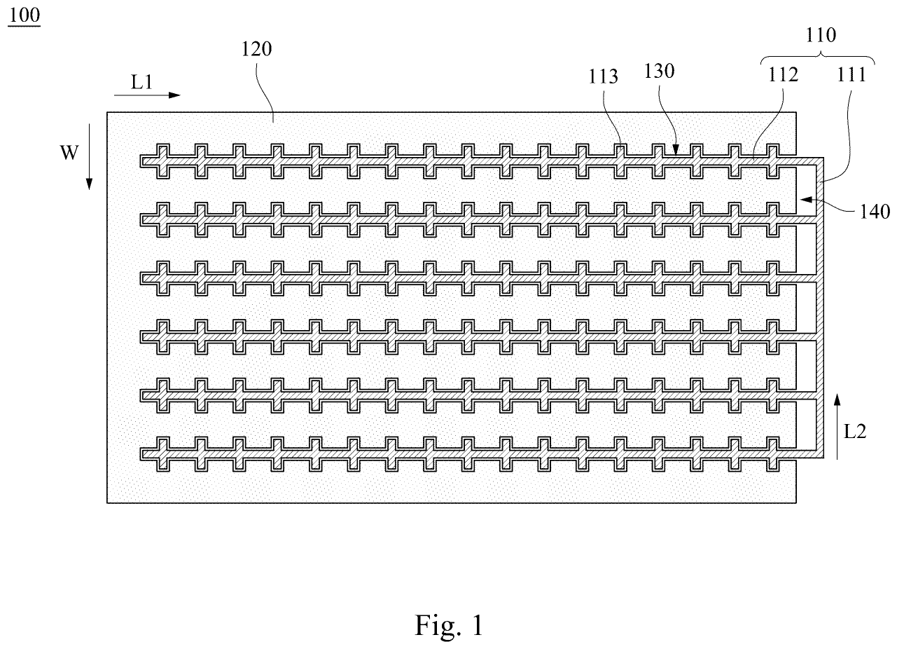

FIG. 1 is a top view of a test element group 100 for a metal routing layer according to one embodiment of the present disclosure. As shown in FIG. 1, the test element group 100 for the metal routing layer includes a line region 110 and a bulk region 120. In some embodiments, the line region 110 and the bulk region 120 are at the same layer, such as the metal routing layer. The line region 110 has a connection portion 111 and a plurality of comb teeth portions 112. The comb teeth portions 112 are connected to and perpendicular to the connection portion 111. Each of the comb teeth portions 112 further has a plurality of extending segments 113 separated from each other. The bulk region 120 surrounds the extending segments 113 of the comb teeth portions 112. The comb teeth portions 112 are separated from the bulk region 120 by a plurality of first gaps 130 that respectively extend along outlines of the comb teeth portions 112. Accordingly, the test element group 100 can be designed to monitor metal-metal short issue induced by micro metal residue in a new metal routing design which cannot be defined by a traditional comb-shaped test element group. With the increasing advancement of manufacturing process, the interconnected semiconductor devices such as diodes, transistors, capacitors and other devices become smaller, and the test element group 100 having the line region 110 and the bulk region 120 can monitor the new metal routing layers and inspect whether there is any micro metal residue inducing metal-metal short issue. Moreover, the area of the bulk region 120 is larger than the area of the traditional comb-shaped test element group, and thus diverse patterns can be defined. The specific shape of the extending segments can be applied to the metal routing layer in integrated circuits simultaneously. In some embodiments, the test element group 100 can be formed on the dies or in the scribe lines between the dies for the spacing test of integrated circuit chips. The line region 110 and the bulk region 120 can be electrically connected to TEG pads respectively, and then a test apparatus with test probes can run the spacing test by contacting TEG pads. The spacing test can provide corresponding electrical characteristics of the metal routing layer of the dies.

As shown in FIG. 1, the test element group 100 further has a second gap 140 between the bulk region 120 and the connection portion 111 of the line region 110. In addition, the comb teeth portions 112 of the line region 110 extend along a lengthwise direction L1 of the bulk region 120. Any two adjacent extending segments 113 of each of the comb teeth portions 112 have the same distance.

The extending segments 113 are line-shaped and parallel to a lengthwise direction L2 of the connection portion 111. Furthermore, each of the comb teeth portions 112 presents a cross-shaped profile when vied from above.

It is to be noted that the connection relationships and the advantages of the elements described above will not be repeated in the following description. In the following statement, various shape segments 113a, 113b, 113c, and 113d will be explained.

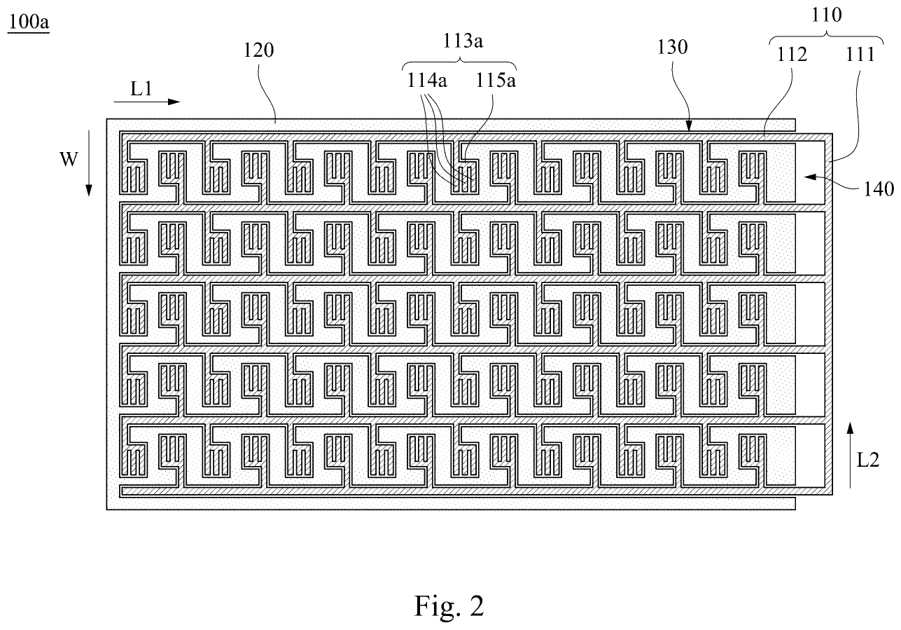

FIG. 2 is a top view of a test element group 100a for a metal routing layer according to another embodiment of the present disclosure. The test element group 100a for the metal routing layer includes the line region 110 and the bulk region 120. The difference between this embodiment and the embodiment of FIG. 1 is that extending segments 113a of the comb teeth portions 112 of the line region 110 of FIG. 2 are fork-shaped. In addition, each of the extending segments 113a of the test element group 100a has three vertical portions 114a and one horizontal portion 115a adjoining the three vertical portions 114a, and one of the vertical portions 114a is longer than the other two vertical portions 114a. The vertical portion 114a extends in the lengthwise direction L2 of the connection portion 111 and the horizontal portion 115a extends in the lengthwise direction L1 of the bulk region 120.

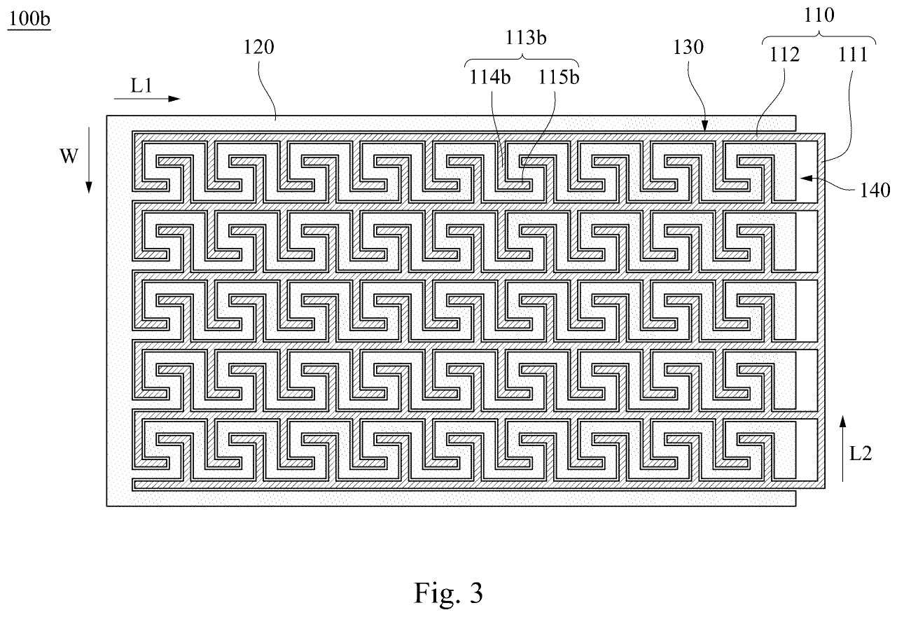

FIG. 3 is a top view of a test element group 100b for a metal routing layer according to yet another embodiment of the present disclosure. The test element group 100b for the metal routing layer includes the line region 110 and the bulk region 120. The difference between this embodiment and the embodiment of FIG. 1 is that extending segments 113b of the comb teeth portions 112 of the line region 110 of FIG. 3 are hook-shaped. In addition, each of the extending segments 113b of the test element group 100b has a vertical portion 114b and a horizontal portion 115b, and an end of the vertical portion 114b adjoins an end of the horizontal portion 115b. The vertical portion 114b extends in the lengthwise direction L2 of the connection portion 111 and the horizontal portion 115b extends in the lengthwise direction L1 of the bulk region 120.

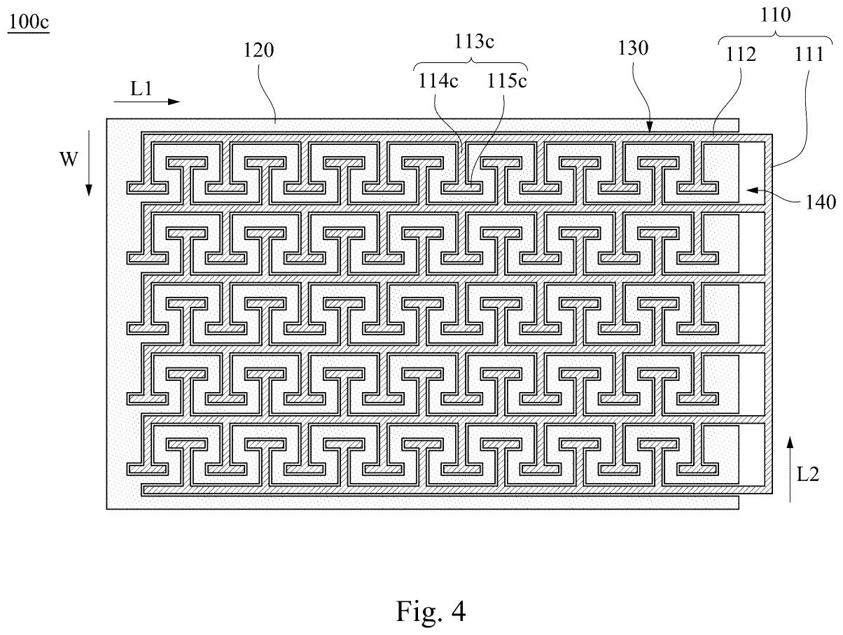

FIG. 4 is a top view of a test element group 100c for a metal routing layer according to still another embodiment of the present disclosure. The test element group 100c for the metal routing layer includes the line region 110 and the bulk region 120. The difference between this embodiment and the embodiment of FIG. 1 is that extending segments 113c of the comb teeth portions 112 of the line region 110 of FIG. 3 are T-shaped. Furthermore, each of the extending segments 113c comprises a vertical portion 114c and a horizontal portion 115c adjoining an end of the vertical portion 114c. The vertical portion 114c extends in the lengthwise direction L2 of the connection portion 111 and the horizontal portion 115c extends in the lengthwise direction L1 of the bulk region 120.

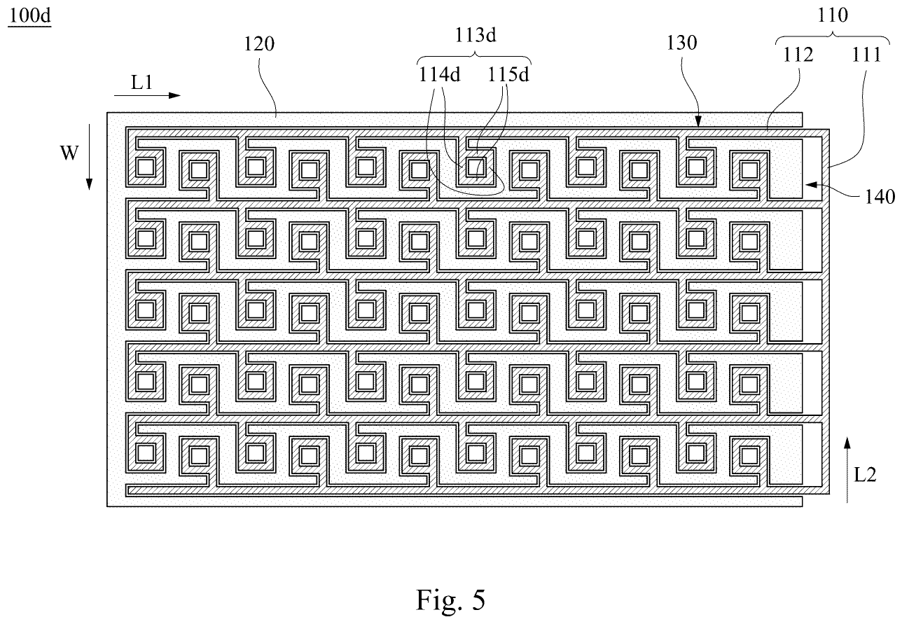

FIG. 5 is a top view of a test element group 100d for a metal routing layer according to one embodiment of the present disclosure. The test element group 100d for the metal routing layer includes the line region 110 and the bulk region 120. The difference between this embodiment and the embodiment of FIG. 1 is that extending segments 113d of the comb teeth portions 112 of the line region 110 of FIG. 3 are 9-shaped. Moreover, each of the extending segments 113d comprises two vertical portions 114d and two horizontal portions 115d that surround a portion of the bulk region 120, and one of the vertical portions 114d is longer than the other vertical portion 114d. The two vertical portions 114d extend in the lengthwise direction L2 of the connection portion 111 and the horizontal portion 115d extends in the lengthwise direction L1 of the bulk region 120.

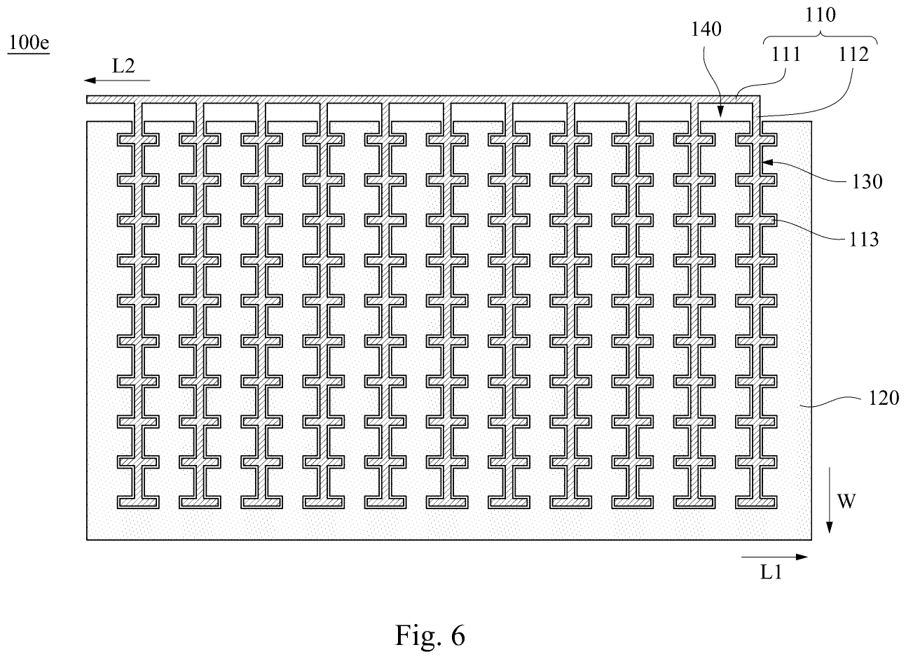

FIG. 6 is a top view of a test element group 100e for a metal routing layer according to another embodiment of the present disclosure. The test element group 100e for the metal routing layer includes the line region 110 and the bulk region 120. The difference between this embodiment and the embodiment of FIG. 1 is that the comb teeth portions 112 of the line region 110 of the test element group 100e extend along a widthwise direction W of the bulk region 120 of the test element group 100e.

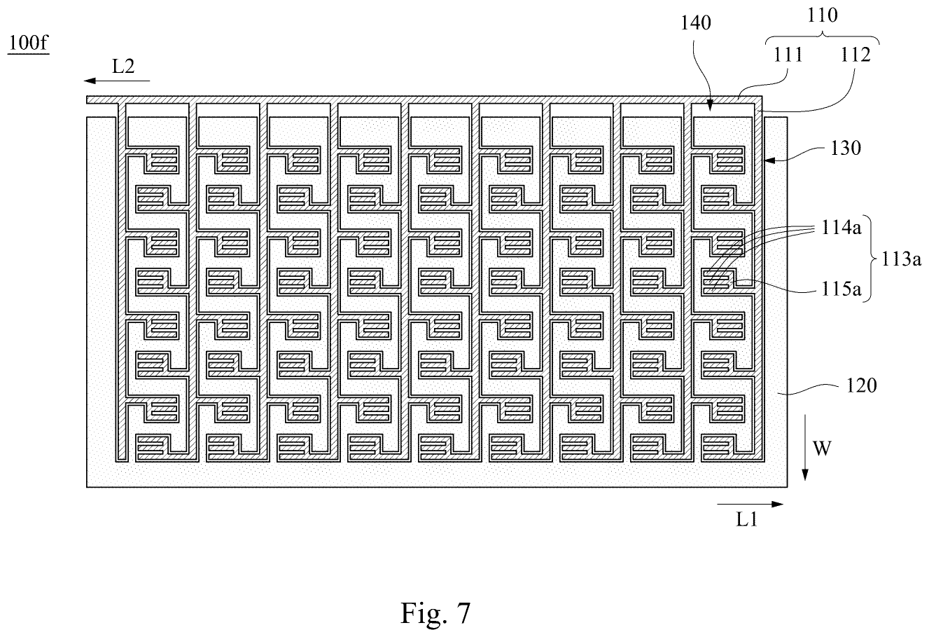

FIG. 7 is a top view of a test element group 100f for a metal routing layer according to yet another embodiment of the present disclosure. The test element group 100f for the metal routing layer includes the line region 110 and the bulk region 120. The difference between this embodiment and the embodiment of FIG. 2 is that the comb teeth portions 112 of the line region 110 of the test element group 100f extend along a widthwise direction W of the bulk region 120 of the test element group 100f.

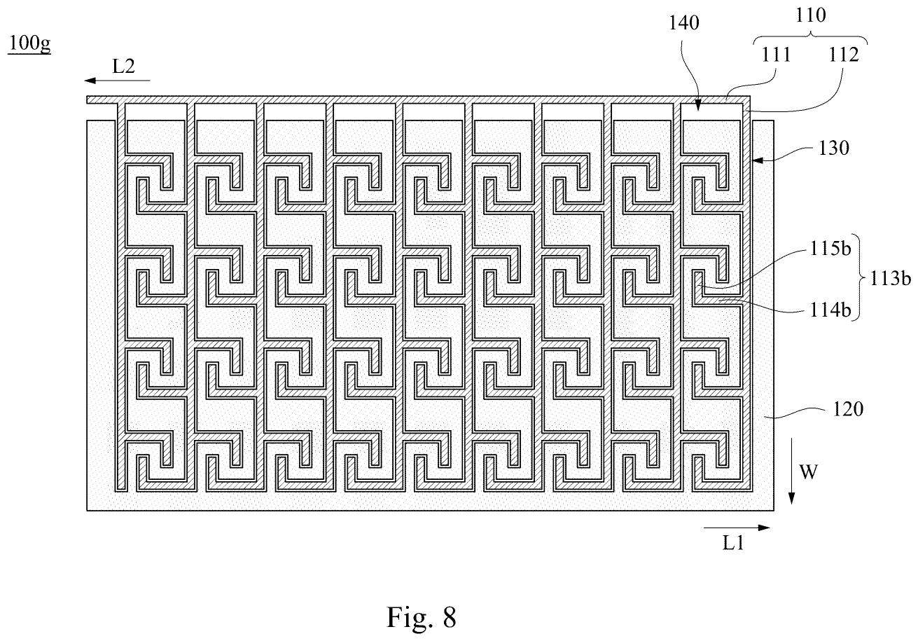

FIG. 8 is a top view of a test element group 100g for a metal routing layer according to still another embodiment of the present disclosure. The test element group 100g for the metal routing layer includes the line region 110 and the bulk region 120. The difference between this embodiment and the embodiment of FIG. 3 is that the comb teeth portions 112 of the line region 110 of the test element group 100g extend along a widthwise direction W of the bulk region 120 of the test element group 100g.

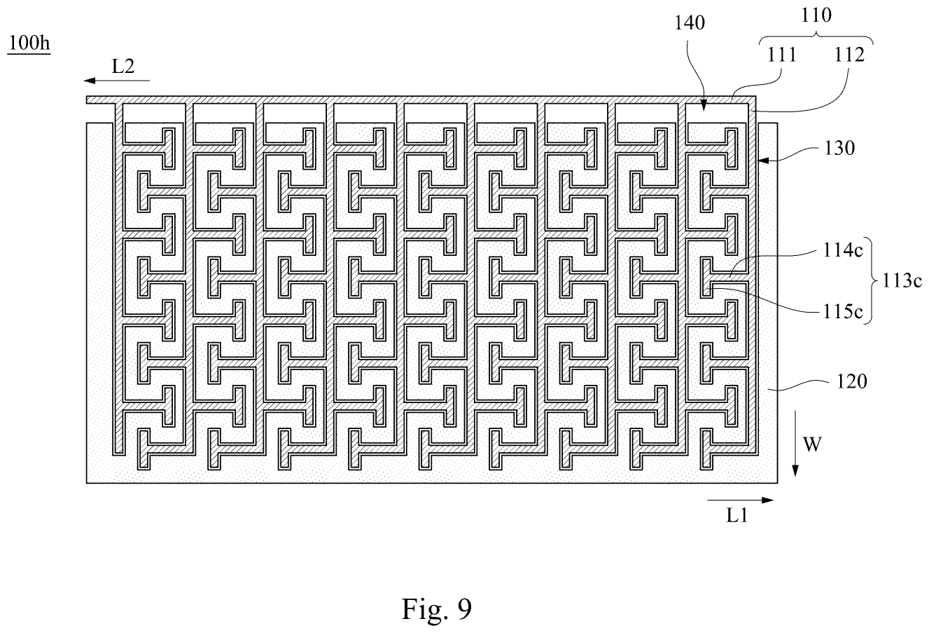

FIG. 9 is a top view of a test element group 100h for a metal routing layer according to one embodiment of the present disclosure. The test element group 100h for the metal routing layer includes the line region 110 and the bulk region 120. The difference between this embodiment and the embodiment of FIG. 4 is that the comb teeth portions 112 of the line region 110 of the test element group 100h extend along a widthwise direction W of the bulk region 120 of the test element group 100h.

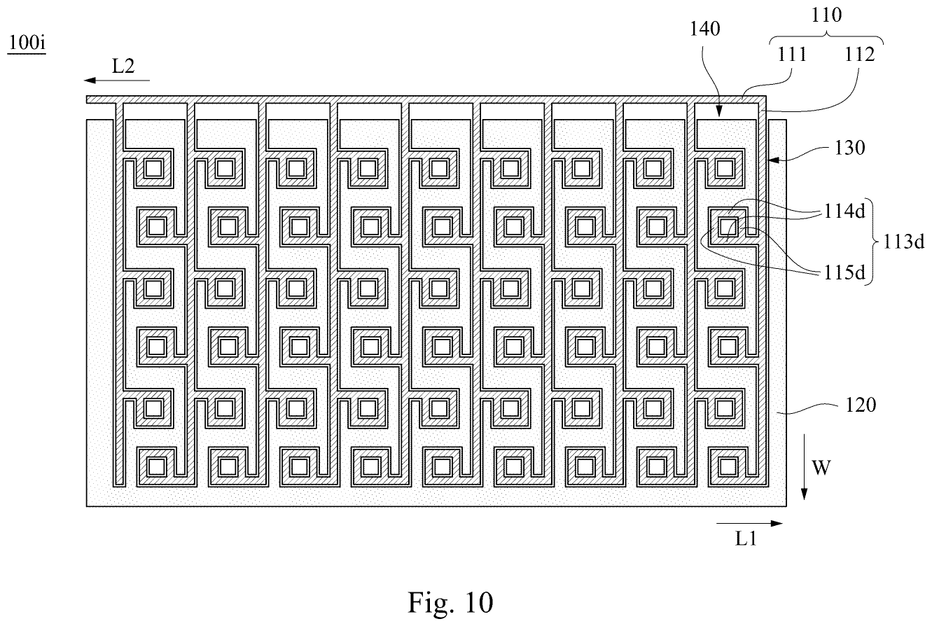

FIG. 10 is a top view of a test element group 100i for a metal routing layer according to another embodiment of the present disclosure. The test element group 100i for the metal routing layer includes the line region 110 and the bulk region 120. The difference between this embodiment and the embodiment of FIG. 5 is that the comb teeth portions 112 of the line region 110 of the test element group 100i extend along a widthwise direction W of the bulk region 120 of the test element group 100i.

During the fabrication of integrated circuits, the aforementioned test element groups 100, and 100a to 100i for metal routing layer can be formed on the dies of the integrated circuits or in the scribe lines of the integrated circuits for the spacing test inspecting whether there is any micro metal residue inducing metal-metal short issue. The test element groups 100 and 100a to 100i having the line region 110 and the bulk region 120 can monitor the new metal routing layers. Different metal routings with various shapes can be achieved by forming the test element groups 100 and 100a to 100i to have different extending segments 113, 113a to 113d. Furthermore, the comb teeth portions 112 of the line region 110 can not only extend along the lengthwise direction L1 of the bulk region 120 but also the widthwise direction W of the bulk region 120 to achieve diverse patterns.

It is to be noted that the pattern of the line region 110 and the bulk region 120 will not be described again and a manufacturing method of test element groups 100 and 100a to 100i for metal routing layer will be described in following statement.

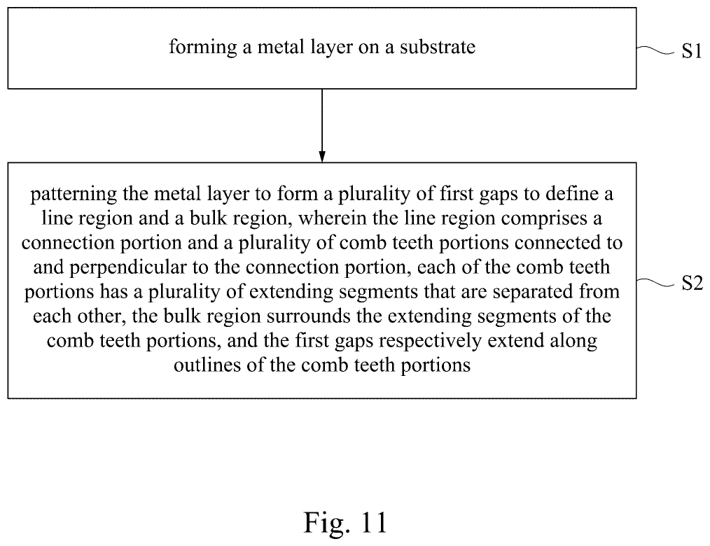

FIG. 11 is a flowchart of a manufacturing method of a test element group (e.g., the test element group 100 of FIG. 1) for a metal routing layer according to some embodiments of the present disclosure. With reference to FIGS. 1 and 11, in step S1, a metal layer is formed on a substrate. Thereafter, in step S2, the metal layer is patterned to form the first gaps 130 to define the line region 110 and the bulk region 120, wherein the line region 110 includes the connection portion 111 and the comb teeth portions 112 connected to and perpendicular to the connection portion 111, each of the comb teeth portions 112 has the extending segments 113 that are separated from each other, the bulk region 120 surrounds the extending segments 113 of the comb teeth portions 112, and the first gaps 130 respectively extend along the outlines of the comb teeth portions 112. In some embodiments, the material of the test element group 100 may be metal or polysilicon.

Moreover, in some embodiments, when patterning the metal layer to form the first gaps 130, the metal layer are simultaneously patterned to form the second gap 140 to define the connection portion 111 of the line region 110 and an edge of the bulk region 120. In addition, patterning the metal layer to form the first gaps 130 and patterning the metal layer to form the second gap 140 can be performed by photolithography. The aforementioned manufacturing method of the test element group 100 can also be applied to other test element groups 100a to 100i. As a result, the test element groups 100 and 100a to 100i with extending segments 113 and 113a to 113d can be formed in integrated circuits to detect metal-metal short issues induced by micro metal residues.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a test element group for a metal routing layer, comprising:
forming a metal layer on a substrate; and
patterning the metal layer to form a plurality of first gaps to define a line region and a bulk region, wherein the line region comprises a connection portion and a plurality of comb teeth portions connected to and perpendicular to the connection portion, each of the comb teeth portions has a plurality of extending segments that are separated from each other, the bulk region surrounds the extending segments of the comb teeth portions, and the first gaps respectively extend along outlines of the comb teeth portions.

2. The manufacturing method of the test element group of claim 1, further comprising:
when patterning the metal layer to form the first gaps, simultaneously patterning the metal layer to form a second gap to define the connection portion of the line region and an edge of the bulk region.

3. The manufacturing method of the test element group of claim 2, wherein patterning the metal layer to form the first gaps and patterning the metal layer to form the second gap are performed by photolithography.

4. The manufacturing method of the test element group of claim 2, wherein the second gap is between the bulk region and the connection portion of the line region.

5. The manufacturing method of the test element group of claim 1, wherein the comb teeth portions of the line region extend along a lengthwise direction of the bulk region.

6. The manufacturing method of the test element group of claim 1, wherein the comb teeth portions of the line region extend along a widthwise direction of the bulk region.

7. The manufacturing method of the test element group of claim 1, wherein any two adjacent extending segments of each of the comb teeth portions have a same distance.

8. The manufacturing method of the test element group of claim 1, wherein the extending segments of each of the comb teeth portions are line-shaped and parallel to a lengthwise direction of the connection portion.

9. The manufacturing method of the test element group of claim 1, wherein each of the comb teeth portions presents a cross-shaped profile when viewed from above.

10. The manufacturing method of the test element group of claim 1, wherein the extending segments of each of the comb teeth portions are fork-shaped.
